(19) United States
(12) Patent Application Publication
(10) Pub. No.: US 2024/0098658 A1
(43) Pub. Date: Mar. 21, 2024

(54) TRANSMITTER INCLUDING PLL WITH DUAL OUTPUTS FOR GENERATING DAC SAMPLING AND LO SIGNALS

(71) Applicant: QUALCOMM Incorporated, San Diego, CA (US)

(72) Inventors: Yi ZENG, San Jose, CA (US); Cheng-Han WANG, San Jose, CA (US); Chan Hong PARK, San Jose, CA (US)

(21) Appl. No.: 17/949,935

(22) Filed: Sep. 21, 2022

(51) Int. Cl. H04W 56/00; H04L 7/033

(52) U.S. Cl. CPC H04W 56/0005; H04L 7/0331

(57) ABSTRACT

An aspect of the disclosure relates to a transmitter including a phase lock loop (PLL) configured to generate a digital-to-analog (DAC) sampling signal and a local oscillator (LO) signal; a digital-to-analog (DAC) converter configured to convert a transmit digital signal into a transmit analog signal based on the DAC sampling signal; and a mixer configured to frequency upconvert the transmit analog signal based on the LO signal.

### FIELD

Aspects of the present disclosure relate generally to transmitters and/or transceivers, and in particular, to a transmitter or transceiver including a phase lock loop (PLL) including at least two outputs for generating a digital-to-analog (DAC) sampling signal and a radio frequency (RF) local oscillator (LO) signal.

### BACKGROUND

A transmitter may be configured to transmit a set of pulses (e.g., ultra-wideband (UWB) pulses) based on a set of data. The signal including the set of pulses may be frequency upconverted to generate a transmit radio frequency (RF) signal. The transmit RF signal may then be amplified by a power amplifier (PA), and provided to an antenna for wireless transmission. Such transmitter may include phase lock loops (PLLs) to generate clocks or periodic oscillating signals used to generate the transmit RF signal. Reducing the number of components in such transmitter is of interest to reduce transmitter size and costs, and conserve power.

### SUMMARY

The following presents a simplified summary of one or more implementations in order to provide a basic understanding of such implementations. This summary is not an extensive overview of all contemplated implementations, and is intended to neither identify key or critical elements of all implementations nor delineate the scope of any or all implementations. Its sole purpose is to present some concepts of one or more implementations in a simplified form as a prelude to the more detailed description that is presented later.

An aspect of the disclosure relates to a transmitter. The transmitter including a phase lock loop (PLL) configured to generate a digital-to-analog (DAC) sampling signal and a local oscillator (LO) signal; a digital-to-analog (DAC) converter configured to convert a transmit digital signal into a transmit analog signal based on the DAC sampling signal; and a mixer configured to frequency upconvert the transmit analog signal based on the LO signal.

Another aspect of the disclosure relates to a method of generating a transmit radio frequency (RF) signal. The method includes phase-frequency locking a feedback signal to a reference signal to generate a digital-to-analog (DAC) sampling signal and a local oscillator (LO) signal; converting a transmit digital signal into a transmit analog signal based on the DAC sampling signal; and frequency upconverting the transmit analog signal to generate the transmit RF signal.

Another aspect of the disclosure relates to an apparatus for generating a transmit analog signal. The apparatus includes a digital pulse shaper configured to generate a transmit digital signal including sets of sample coefficients corresponding to a set of consecutive pulses, respectively, wherein the sets of sample coefficients are generated in accordance with a fractional oversampling ratio (OSR); and a digital-to-analog converter (DAC) configured to generate the transmit analog signal based on the transmit digital signal.

Another aspect of the disclosure relates to a method of generating a transmit analog signal. The method includes generating a transmit digital signal including sets of sample coefficients corresponding to a set of consecutive pulses, respectively, wherein the sets of sample coefficients are generated in accordance with a fractional oversampling ratio (OSR); and converting the transmit digital signal into the transmit analog signal.

To the accomplishment of the foregoing and related ends, the one or more implementations include the features hereinafter fully described and particularly pointed out in the claims. The following description and the annexed drawings set forth in detail certain illustrative aspects of the one or more implementations. These aspects are indicative, however, of but a few of the various ways in which the principles of various implementations may be employed and the description implementations are intended to include all such aspects and their equivalents.

### BRIEF DESCRIPTION OF THE DRAWINGS

FIG. 1 illustrates a block diagram of an example transmitter in accordance with an aspect of the disclosure.

FIG. 2 illustrates a graph of an example transmit analog pulse in accordance with another aspect of the disclosure.

FIG. 3 illustrates a graph of an example transmit digital pulse in accordance with another aspect of the disclosure.

FIG. 4 illustrates a graph of a frequency spectrum of an example transmit analog pulse in accordance with another aspect of the disclosure.

FIG. 5A illustrates a graph of an example set of consecutive transmit digital pulses in accordance with another aspect of the disclosure.

FIG. 5B illustrates a table depicting digital sample coefficients of at least some of the first set of consecutive transmit digital pulses and transmit digital signal associated with FIG. 5A in accordance with another aspect of the disclosure.

FIG. 6A illustrates a graph of another example set of consecutive transmit digital pulses in accordance with another aspect of the disclosure.

FIG. 6B illustrates a table depicting digital sample coefficients of at least some of the set of consecutive transmit digital pulses and transmit digital signal associated with FIG. 6A in accordance with another aspect of the disclosure.

FIG. 7 illustrates a block diagram of another example transmitter in accordance with another aspect of the disclosure.

FIG. 8 illustrates a block diagram of an example phase lock loop (PLL) in accordance with another aspect of the disclosure.

FIG. 9 illustrates a table comparing a fixed oversampling ratio (OSR) with variable OSRs for generating a transmit digital signal in a transmitter in accordance with another aspect of the disclosure.

FIG. 10A illustrates a graph of another example set of consecutive transmit digital pulses in accordance with another aspect of the disclosure.

FIG. 10B illustrates a table depicting digital sample coefficients of at least some of the set of consecutive transmit digital pulses and transmit digital signal associated with FIG. 10A in accordance with another aspect of the disclosure.

FIG. 11A illustrates a table depicting digital sample coefficients for a set of consecutive transmit digital pulses sampled in accordance with a fractional oversampling ratio (OSR) of 5.5 in accordance with another aspect of the disclosure.

FIG. 11B illustrates a table depicting digital sample coefficients for a set of consecutive transmit digital pulses sampled in accordance with a fractional oversampling ratio (OSR) of 4.25 in accordance with another aspect of the disclosure.

FIG. 12 illustrates a block diagram of at least a portion of an example transmitter in accordance with another aspect of the disclosure.

FIG. 13 illustrates a flow diagram of an example method of generating a transmit radio frequency (RF) signal in accordance with another aspect of the disclosure.

FIG. 14 illustrates a flow diagram of an example method of generating a transmit analog signal in accordance with another aspect of the disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

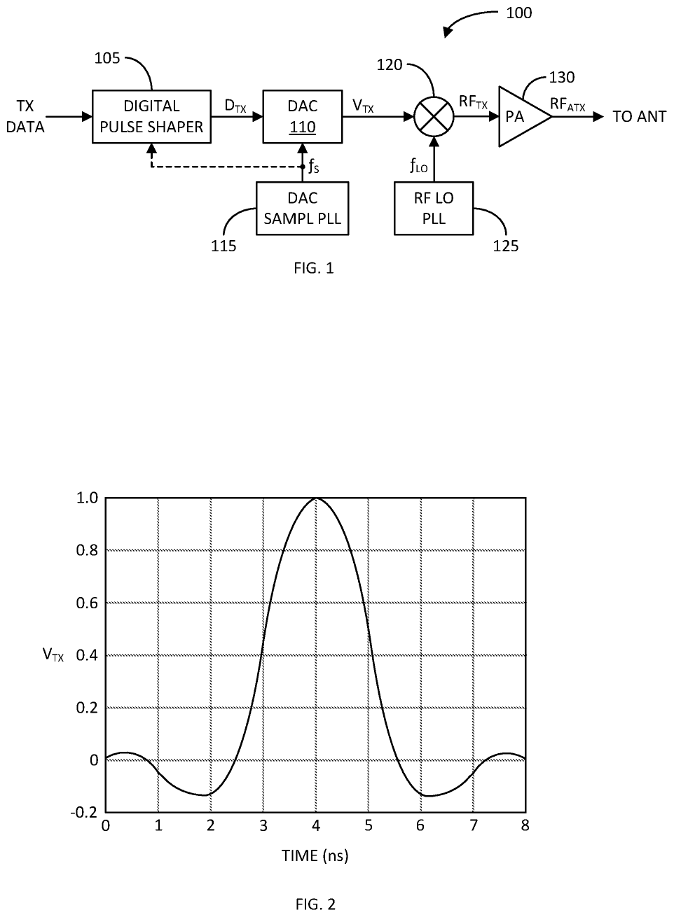

FIG. 1 illustrates a block diagram of an example transmitter 100 in accordance with an aspect of the disclosure. The transmitter 100 includes a digital pulse shaper 105, a digital-to-analog converter (DAC) 110, a DAC sampling phase lock loop (PLL) 115, a frequency-upconverting mixer 120, a radio frequency (RF) local oscillator (LO) PLL 125, and a power amplifier (PA) 130. It shall be understood that the transmitter 100 is an example, and the transmitter 100 may be configured differently including more or less components as exemplified in FIG. 1. Further, it shall be understood that the transmitter 100 may be part of a transceiver including an associated receiver.

The digital pulse shaper 105 is configured to receive transmit (Tx) data (which in some applications could be a repeated pre-defined data set), and generate a transmit digital signal D_{TX} based on the Tx data. For example, the transmit digital signal D_{TX} may be samples of a pulse, such as an ultra-wideband (UWB) pulse, indicative of logic information of the current Tx data. For instance, if the current Tx data is a logic one (1), the digital pulse shaper 105 may generate the transmit digital signal D_{TX} to include a positive pulse (e.g., the main pulse lobe initially rises and then falls). If the current Tx data is a logic zero (0), the digital pulse shaper 105 may generate transmit digital signal D_{TX} to include a negative pulse (e.g., the main pulse lobe initially falls and then rises).

Alternatively, the digital pulse shaper 105 may generate the transmit digital signal D_{TX} to represent a ternary logic signal. For example, the Tx input data could be 2 bits of parallel inputs at 500 mega bits per second (Mbps), with bit<1> as a logic one (1) and bit<0> as another logic one (1), then the digital pulse shaper 105 may generate the transmit digital signal D_{TX} to include a positive pulse. Similarly, if the 2 bits of parallel inputs send a logic one (1) at bit<1> and a logic zero (0) at bit<0>, then the digital pulse shaper 105 may generate the transmit digital signal D_{TX} to include a negative pulse. And if bit<1> of the 2 bits Tx data input is a logic zero (0), regardless of the status of bit<0>, which could be considered as a “don't care”, then the digital pulse shaper 105 may generate the transmit digital signal D_{TX} to include no pulse (or an absence of a pulse).

With regard to UWB pulses, UWB connectivity is a short-range, wireless communication protocol that operates with a very high frequency as compared to other short-range wireless communication technologies (e.g., Bluetooth, wide local area network (WLAN), Zigbee, or the like), and uses a relatively wide frequency band (e.g., 500 MHz or greater) as compared to other short-range wireless communication technologies, which makes UWB useable for high-resolution positioning and localization purposes. In some cases, UWB technology may be used for location discovery, device ranging, or the like. In some cases, a UWB transmitter (e.g., the transceiver 100 or 700 implemented as a UWB transmitter) may transmit numerous pulses across the wide spectrum frequency, and a corresponding UWB receiver (e.g., located at another UWB-enabled device) may translate the pulses into data.

The digital pulse shaper 105 may generate the transmit digital signal D_{TX} based on a DAC sampling signal f_{S} generated by the DAC sampling PLL 115. For simplicity's sake, the term “f_{S}” may refer to the DAC sampling signal or the frequency of the DAC sampling signal depending how the term is used. As discussed in more detail further herein, a pulse may have a main lobe width represented as a unit interval (UI). For example, in the pulses exemplified herein, each pulse has a UI of two (2) nanoseconds (ns), but it shall be understood that the UI may be different depending on the requirements and application for the transmitter. The DAC sampling signal f_{S} sets the number of samples of the transmit digital signal D_{TX} to generate a UI of a pulse. If the number of samples to generate a UI of a pulse is two (2), it may be said that the DAC sampling signal f_{S} has an oversampling ratio (OSR) of 2×. If the number of samples to generate a UI of a pulse is four (4), the DAC sampling signal f_{S} has an OSR of 4×. And, if the number of samples to generate a UI of a pulse is eight (8), the DAC sampling signal f_{S} has an OSR of 8×.

The pulses (including no pulse intervals) of the transmit digital signal D_{TX} are generated every UI. As discussed above, in the examples provided herein, the UI is 2 ns. Accordingly, the pulses (including no pulse intervals) are generated at a rate f_{P} of 500 mega Hertz (MHz) (e.g., update every 2 ns). If the OSR is 2×, then the frequency of the DAC sampling signal f_{S} is one (1) giga Hertz (GHz) (e.g., 2×500 MHz). If the OSR is 4×, then the frequency of the DAC sampling signal f_{S} is 2 GHz (e.g., 4×500 MHz). And, if the OSR is 8×, then the frequency of the DAC sampling signal f_{S} is 4 GHz (e.g., 8×500 MHz).

The transmit digital signal D_{TX} is provided to the DAC 110, which is configured to convert the transmit digital signal D_{TX} into a transmit analog signal V_{TX}. Although in example implementations described herein, the DAC sampling signal f_{S} generated by the DAC sampling PLL 115 is provided to the digital pulse shaper 105, the DAC sampling signal f_{S} controls the rate at which the DAC 110 converts the transmit digital signal D_{TX} into a transmit analog signal V_{TX}, as discussed further herein.

The frequency-upconverting mixer 120 is configured to mix the transmit analog signal V_{TX} with an LO signal f_{LO} generated by the RF LO PLL 125 to generate a transmit RF signal RF_{TX}. For simplicity's sake, the term “f_{LO}” may refer to the LO signal or the frequency of the LO signal depending how the term is used. It shall be understood that the transmitters described herein may include more than one frequency-upconverting mixer stage. For example, the transmitter 100 may include a first mixer stage configured to frequency upconvert the transmit analog signal V_{TX} into an intermediate frequency (IF) transmit signal, and then a second mixer stage configured to frequency upconvert the IF transmit signal into the transmit RF signal RF_{TX}. In this example, the LO signal f_{LO} may serve as the carrier component of the transmit RF signal RF_{TX}.

The PA 130 is configured to amplify the transmit RF signal RF_{TX} to a particular power level for transmission to one or more wireless devices (e.g., in the case of communication applications) and/or one or more objects (e.g., in the case of radar applications). The output of the PA 130 may be coupled to an antenna to radiate the amplified transmit RF signal RF_{ATX} to effectuate the remote transmission to the one or more wireless devices and/or objects. As alluded to above, the transmitter 100 may include additional components between the PA 130 and the antenna, such as a directional coupler, power detector, diplexer, duplexer, filter, etc.

FIG. 2 illustrates a graph of an example transmit analog pulse V_{TX} in accordance with another aspect of the disclosure. The x- or horizontal-axis of the graph represents time in nanoseconds (ns) extending from zero (0) to 8 ns. The y- or vertical-axis of the graph represents normalized amplitude with respect to a peak of the transmit analog pulse V_{TX}, extending from −0.2 to 1.0.

As illustrated, the example transmit analog pulse V_{TX} may be in the form of a raised-cosine pulse. It may not be desirable for such pulse to take on a square or rectangular shape as such pulse has a relatively wide spectrum. If the transmission of the amplified transmit RF signal RF_{ATX} is within an assigned frequency channel among a set of defined frequency-staggered channels, there may be a specification as to the width of the spectrum of the transmit RF signal RF_{ATX} so as not to interfere with the transmission of an adjacent frequency channel. Such specification is often referred to as a spectrum emission mask (SEM). On the other hand, the raised-cosine pulse has a relatively narrow spectrum, and may be preferred over a square or rectangular pulse based on the governing SEM.

In this example, the raised-cosine pulse V_{TX} has a main lobe centered within a UI of 2 ns; for example, within UI extending from 3 ns to 5 ns. Further, the raised-cosine pulse V_{TX} has a sinewave-looking leader extending from 0 ns to 3 ns, and a sinewave-looking trailer extending from 5 ns to 8 ns. Because raised-cosine pulse V_{TX} has relatively smooth curves, compared to the step changes of a square or rectangular pulse, the spectrum of the raised-cosine pulse V_{TX} is narrow compared to a square or rectangular pulse with the same UI.

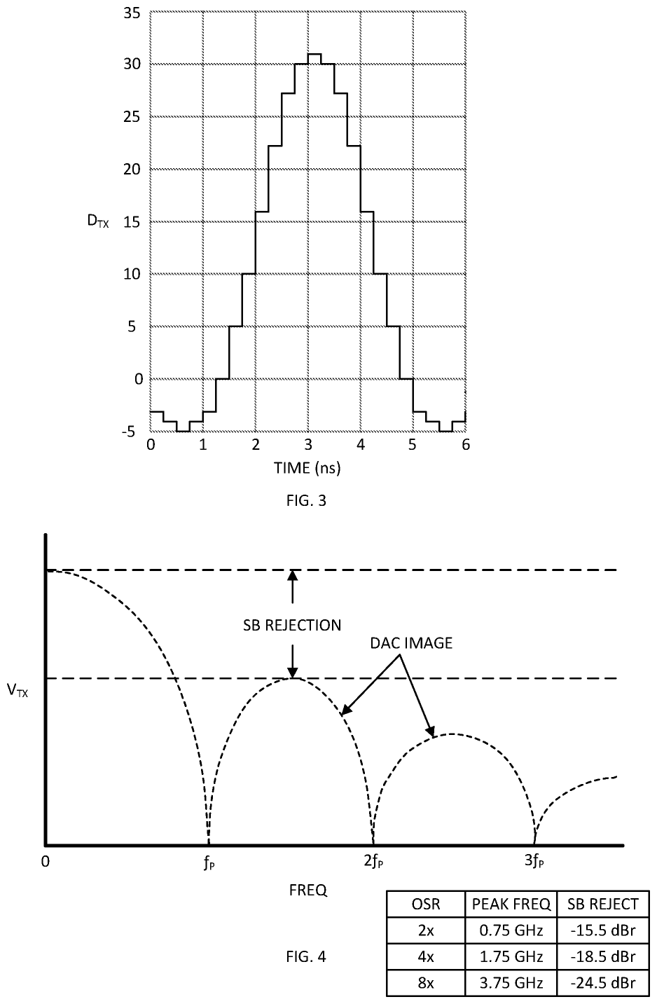

FIG. 3 illustrates a graph of an example transmit digital pulse D_{TX} in accordance with another aspect of the disclosure. The x- or horizontal-axis of the graph represents time in nanoseconds (ns) extending from zero (0) to 6 ns. The y- or vertical-axis of the graph represents amplitude of the transmit digital pulse D_{TX}, extending from −5 to 35.

The transmit digital pulse D_{TX} may be an example of a transmit digital signal generated by the digital pulse shaper 105 that results in the DAC 110 generating the raised-cosine pulse V_{TX}, as discussed with reference to FIG. 2. In this example, the transmit digital pulse D_{TX} may extend three (3) UIs, with a leader portion of the pulse extending from 0 to 2 ns, a main lobe of the pulse extending from 2 ns to 4 ns, and a trailer portion of the pulse extending from 4 ns to 6 ns. With the pulse shaper's coefficients being quantized and the pulse transmit length limited in this example, this may be a more practical implementation.

Further, in accordance with this example, the transmit digital pulse D_{TX} has an oversampling ratio (OSR) of 8×. That is, for each UI (e.g., 2 ns), there are eight (8) samples. For example, within the UI corresponding to the main lobe of the pulse, the eight (8) samples correspond to: (1) time interval 2 ns to 2.25 ns where D_{TX} has a sample coefficient of 16; (2) time interval 2.25 ns to 2.5 ns where D_{TX} has a sample coefficient of 22; (3) time interval 2.5 ns to 2.75 ns where D_{TX} has a sample coefficient of 27; (4) time interval 2.75 ns to 3 ns where D_{TX} has a sample coefficient of 30; (5) time interval 3 ns to 3.25 ns where D_{TX} has a sample coefficient of 31; (6) time interval 3.25 ns to 3.5 ns where D_{TX} has a sample coefficient of 30; (7) time interval 3.5 ns to 3.75 ns where D_{TX} has a sample coefficient of 27; and (8) time interval 3.75 ns to 4 ns where D_{TX} has a sample coefficient of 22. The leader portion UI (e.g., between 0 ns to 2 ns) and the trailer portion UI (e.g., 4 ns to 6 ns) each also have eight (8) samples. Although, in this example, the OSR is eight (8), it shall be understood that the transmit digital signal D_{TX} may be generated with different OSRs, as discussed further herein.

In this example, the transmit digital pulse D_{TX} may be quantized to a signed five (5) bit, ranging from −31 to +31. The example transmit digital pulse D_{TX}, which is a positive pulse, extends from a sample coefficient of −5 to a sample coefficient of +31. An example of a negative transmit digital pulse D_{TX} may extend from +5 to −31, as discussed further herein. An extra bit may also be added to extend the range to −47 to +47 for cases where data pulses could overlap with each other so that a higher peak is expected. It shall be understood that the quantization of the transmit digital pulse D_{TX} may be different to include more or less bits depending on various design factors.

FIG. 4 illustrates a graph of a frequency spectrum of an example transmit analog pulse V_{TX} in accordance with another aspect of the disclosure. The x- or horizontal-axis of the graph represents normalized frequency in terms of the pulse rate f_{P}, extending from zero (0) where the center of the main peak lies in frequency to beyond 2f_{P}. The y- or vertical-axis represents magnitude of the frequency constituents of the transmit analog pulse V_{TX}. As the transmit signal pulses are transmitted at 500 Mbps (f_{P}), null happen at every 500 MHz.

Accompanying the graph is a table illustrating the effects of different OSRs on the spectrum of the transmit analog pulse V_{TX}. The table includes a left column representing the different OSRs (e.g., OSR=2× in row 1; OSR=4× in row 2; and OSR=8× in row 3). The middle column of the table represents the frequency of the closest sideband associated with DAC image (e.g., 0.75 GHz in row 1; 1.75 GHz in row 2; and 3.75 GHz in row 3; where UI is 2 ns or the pulse rate f_{P} is at 500 MHz). The right column of the table represents the sideband (SB) rejection or the amount of decibels relative to a reference (dBr) below the main peak (reference) where the magnitude of the closest sideband or first image lies (e.g., −15.5 dBr in row 1; −18.5 dBr in row 2; and −24.5 dBr in row 3).

As FIG. 4 illustrates, the higher the OSR, the farther away in frequency is the closest sideband or first image, and the lower in magnitude is the peak of the closest sideband or first image relative to the main peak. As an example, a SEM may specify a sideband rejection of −18 dBr. In such case, the OSR=2× would be insufficient to meet the −18 dBr SEM requirement as it can only achieve a sideband rejection of −15.5 dBr. The OSR=4× would marginally meet the −18 dBr SEM requirement with a sideband rejection of −18.5 dBr, which may not provide sufficient margin to take into account tolerances in the design. However, the OSR 8× with a sideband rejection of −24.5 dBr may provide sufficient margin beyond the −18 dBr SEM requirement that it may be suitable for such application. Higher OSRs (e.g., 16× or more) may provide improved sideband rejection, but would result in significantly higher DAC sampling frequency f_{S} (e.g., 16×500 MHz=8 GHz) that would adversely impact power consumption and design complexity.

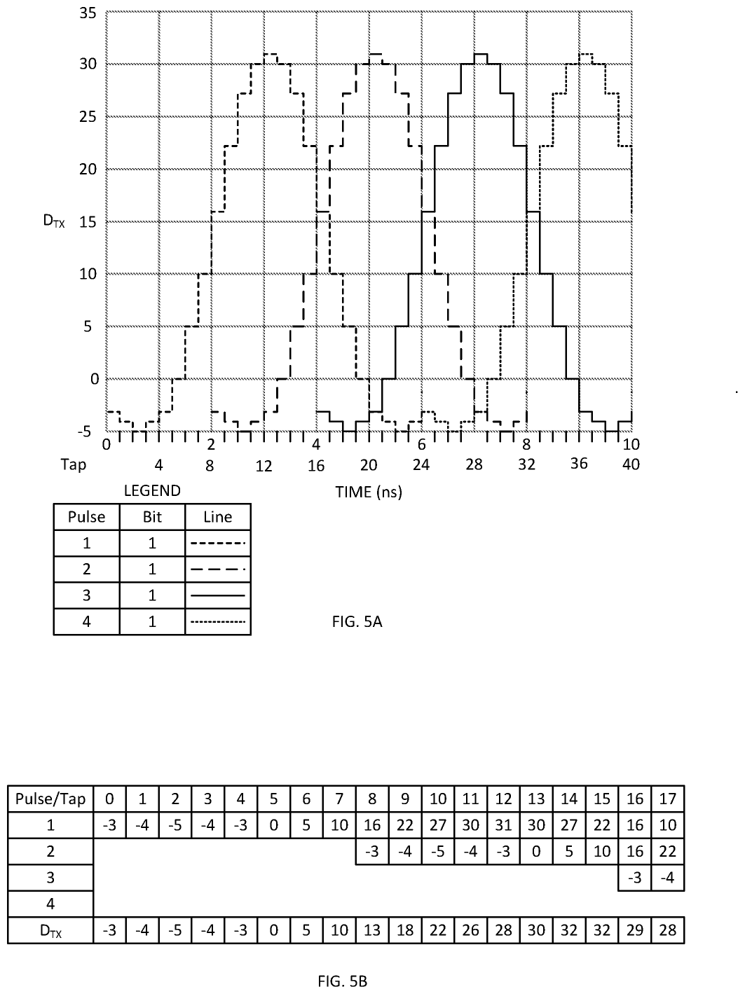

FIG. 5A illustrates a graph of an example set of consecutive transmit digital pulses D_{TX} in accordance with another aspect of the disclosure. The x- or horizontal-axis of the graph represents time in nanoseconds (ns) extending from zero (0) to 10 ns. The y- or vertical-axis of the graph represents amplitude of the transmit digital pulse D_{TX}, extending from −5 to 31. A table, accompanying the graph, is provided as a legend to identify each of the pulses and the bit each of the pulses represents.

In this example, the set of consecutive transmit digital pulses D_{TX} are a set of positive pulses, which may represent a digital stream of four consecutive ones (1s) (e.g., 1/1/1/1). As previously discussed, each pulse may extend three (3) UIs with a leader portion spanning the first UI, the main lobe portion spanning the second UI, and the trailer portion spanning the third UI. In accordance with the ongoing example, a UI may span a 2 ns interval.

For example, the first pulse (“pulse 1”), represented as a small, dashed line, extends from 0 ns to 6 ns, with its leader between 0 to 2 ns, its main lobe between 2 ns to 4 ns, and its trailer between 4 ns to 6 ns. The second pulse (“pulse 2”), represented as a large, dashed line, extends from 2 ns to 8 ns, with its leader between 2 ns to 4 ns, its main lobe between 4 ns to 6 ns, and its trailer between 6 ns to 8 ns. The third pulse (“pulse 3”), represented as a solid line, extends from 4 ns to 10 ns, with its leader between 4 ns to 6 ns, its main lobe between 6 ns to 8 ns, and its trailer between 8 ns to 10 ns. The fourth pulse (“pulse 4”), represented as a dotted line, extends from 6 ns to 12 ns, with its leader between 6 ns to 8 ns, its main lobe between 8 ns to 10 ns, and its trailer between 10 ns to 12 ns (not shown because it extends beyond the graph's time dimension).

Note that the pulses overlap with each other. For example, the first and second pulses overlap during time interval 2 ns to 6 ns; the first, second, and third pulses overlap during time interval 4 ns to 6 ns; the second, third, and fourth pulses overlap during time interval 6 ns to 8 ns; and the third and fourth pulses overlap during time interval 8 ns to 10 ns. Thus, as discussed, since each pulse spans three (3) UIs and adjacent pulses are spaced apart by one (1) UI, then each pulse overlaps with an adjacent pulse by two (2) UIs. The sample coefficient of the transmit digital signal D_{TX} at a particular sample or tap (sample index) is the cumulative sum of the sample coefficients of the overlapping pulses. For example, the sample coefficient of the transmit digital signal D_{TX} at tap 16 is 29 (e.g., 16 from pulse 1, 16 from pulse 2, and −3 from pulse 3; or 16+16−3=29).

FIG. 5B illustrates a table depicting sample coefficients of the first, second, and third consecutive pulses of FIG. 5A and transmit digital signal D_{TX} at various taps in accordance with another aspect of the disclosure. The left column represents the pulses and transmit digital signal D_{TX} (e.g., pulse 1 in row 1, pulse 2 in row 2, pulse 3 in row 3, pulse 4 in row 4, and D_{TX} in row 5). The remaining columns, from left-to-right, represents the sets of sample coefficients of the pulses and the transmit digital signal D_{TX} corresponding to taps zero (0) to 17, respectively.

For example, at tap 0, the first pulse has a sample coefficient of −3. Per this example, there are no other pulses overlapping with the first pulse at tap 0. Accordingly, the transmit digital signal D_{TX} also has a sample coefficient of −3 at tap 0. For the first UI (e.g., taps 0 to 7), there are no pulses overlapping with the first pulse; and thus, the sample coefficients for the first pulse, as well as the transmit digital signal D_{TX}, for taps 1-7 are −4, −5, −4, 3, 0, 5, and 10, respectively.

At tap 8 (or the beginning of the second UI), the first pulse begins to overlap with the second pulse. Accordingly, the sample coefficient of the first pulse at tap 8 is 16, and the sample coefficient of the second pulse at tap 8 is −3. Thus, the transmit digital signal D_{TX} at tap 8 has a sample coefficient of 13 (e.g., 16−3=13). Similarly, for the second UI (e.g., taps 8 to 15), only the first and second pulses overlap; and thus, the sample coefficients for the first and second pulses, and the transmit digital signal D_{TX} for taps 9-15 are [22, −4, 18], [27, −5, 22], [30, −4, 26], [31, −3, 28], [30, 0, 30], [27, 5, 32], and [22, 10, 32], respectively.

At tap 16 (or the beginning of the third UI), the first and second pulses begin to overlap with the third pulse. Accordingly, the sample coefficient of the first pulse at tap 16 is 16, the sample coefficient of the second pulse at tap 16 is 16, and the sample coefficient of the third pulse at tap 16 is −3. Thus, the transmit digital signal D_{TX} at tap 16 has a sample coefficient of 29 (e.g., 16+16−3=29). Similarly, for the third UI (e.g., taps 16 to 23), only the first, second, and third pulses overlap; and thus, the sample coefficients for the first, second, and third pulses, and the transmit digital signal D_{TX} for tap 17 is [10, 22, −4, 28]. The sample coefficients for the pulses and the transmit digital signal D_{TX} may be determined for the remaining taps in the third UI, the fourth UI, and so on.

The digital pulse shaper 105 may include a memory (e.g., a firmware register) with the set of sample coefficients for each positive pulse (as well as a negative pulse, as discussed further herein), a counter driven by the DAC sampling signal f_{S} to keep track of the taps, and a summer to sum the sample coefficients of the overlapping pulses to generate the transmit digital signal D_{TX} based on the received Tx data.

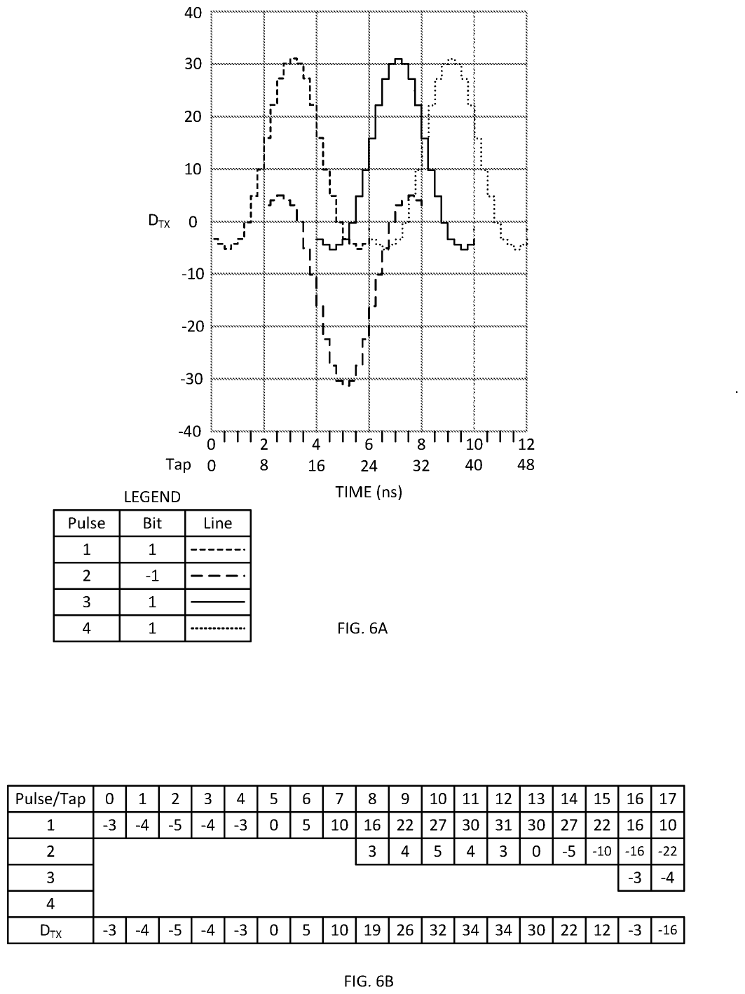

FIG. 6A illustrates a graph of another example set of consecutive transmit digital pulses D_{TX} in accordance with another aspect of the disclosure. The x- or horizontal-axis of the graph represents time in nanoseconds (ns) extending from zero (0) to 12 ns. The y- or vertical-axis of the graph represents amplitude of the transmit digital signal D_{TX}, extending from −40 to +40. A table, accompanying the graph, is provided as a legend to identify each of the pulses and the bit each of the pulses represents.

In this example, the set of consecutive transmit digital pulses D_{TX} are a set of pulses representing a bit stream of 1/1/1/1. As previously discussed, each pulse may extend three (3) UIs with a leader portion spanning the first UI, the main lobe portion spanning the second UI, and a trailer portion spanning the third UI. In accordance with the ongoing example, a UI may span a 2 ns interval.

For example, the first pulse (“pulse 1”), represented as a small, dashed line, extends from 0 ns to 6 ns, with its leader between 0 to 2 ns, its main lobe between 2 ns to 4 ns, and its trailer between 4 ns to 6 ns. The second pulse (“pulse 2”), represented as a large, dashed line, extends from 2 ns to 8 ns, with its leader between 2 ns to 4 ns, its main lobe between 4 ns to 6 ns, and its trailer between 6 ns to 8 ns. The third pulse (“pulse 3”), represented as a solid line, extends from 4 ns to 10 ns, with its leader between 4 ns to 6 ns, its main lobe between 6 ns to 8 ns, and its trailer between 8 ns to 10 ns. The fourth pulse (“pulse 4”), represented as a dotted line, extends 6 ns to 12 ns, with its leader between 6 ns to 8 ns, its main lobe between 8 ns to 10 ns, and its trailer between 10 ns to 12 ns.

As previously discussed, the pulses overlap with each other. For example, the first and second pulses overlap during time interval 2 ns to 4 ns; the first, second, and third pulses overlap during time interval 4 ns to 6 ns; the second, third, and fourth pulses overlap during time interval 6 ns to 8 ns; and the third and fourth pulses overlap during time interval 8 ns to 10 ns. Thus, as discussed, since each pulse spans three (3) UIs and adjacent pulses are spaced apart by one (1) UI, then each pulse overlaps with an adjacent pulse by two (2) UIs. Also, as previously discussed, the sample coefficient of the transmit digital signal D_{TX} at a particular sample or tap is the cumulative sum of the sample coefficients of the overlapping pulses.

FIG. 6B illustrates a table depicting sets of sample coefficients of the first, second, and third pulses of FIG. 6A and the transmit digital signal D_{TX} at various taps in accordance with another aspect of the disclosure. The left column represents the pulses and the transmit digital signal D_{TX} (e.g., pulse 1 in row 1, pulse 2 in row 2, pulse 3 in row 3, pulse 4 in row 4, and D_{TX} in row 5). The remaining columns, from left-to-right, represents the different sample coefficients of the pulses and the transmit digital signal D_{TX} corresponding to taps zero (0) to 17, respectively.

Similar to the previous example, for the first UI (e.g., taps 0 to 7), there are no pulses overlapping with the first pulse; and thus, the sample coefficients for the first pulse, as well as the transmit digital signal D_{TX}, for taps 0-7 are −3, −4, −5, −4, −3, 0, 5, and 10, respectively.

At tap 8 (or the beginning of the second UI), the first pulse begins to overlap with the second pulse. In contrast to the previous example, the second pulse is a negative pulse; and accordingly, has a different (e.g., opposite sign) set of sample coefficients than a positive pulse. Accordingly, the sample coefficient of the first pulse at tap 8 is 16, and the sample coefficient of the second pulse at tap 8 is 3. Thus, the transmit digital signal D_{TX} at tap 8 has a sample coefficient of 19 (e.g., 16+3=19). Similarly, for the second UI (e.g., taps 8 to 15), only the first and second pulses overlap; and thus, the sample v coefficients for the first and second pulses, and the transmit digital signal D_{TX} for taps 9-15 are [22, 4, 26], [27, 5, 32], [30, 4, 34], [31, 3, 34], [30, 0, 30], [27, −5, 22], and [22, −10, 12], respectively.

At tap 16 (or the beginning of the third UI), the first and second pulses begin to overlap with the third pulse. Accordingly, the sample coefficient of the first pulse at tap 16 is 16, the sample coefficient of the second pulse at tap 16 is −16, and the sample coefficient of the third pulse at tap 16 is −3. Thus, the transmit digital signal D_{TX} at tap 16 has a sample coefficient of −3 (e.g., 16−16−3=−3). Similarly, for the third UI (e.g., taps 16 to 23), only the first, second, and third pulses overlap; and thus, the sample coefficients for the first, second, and third pulses, and the transmit digital signal D_{TX} for tap 17 is [10, −22, −4, −16]. The sample coefficients for the pulses and the transmit digital signal D_{TX} may be determined for the remaining taps in the third UI, the fourth UI, and so on.

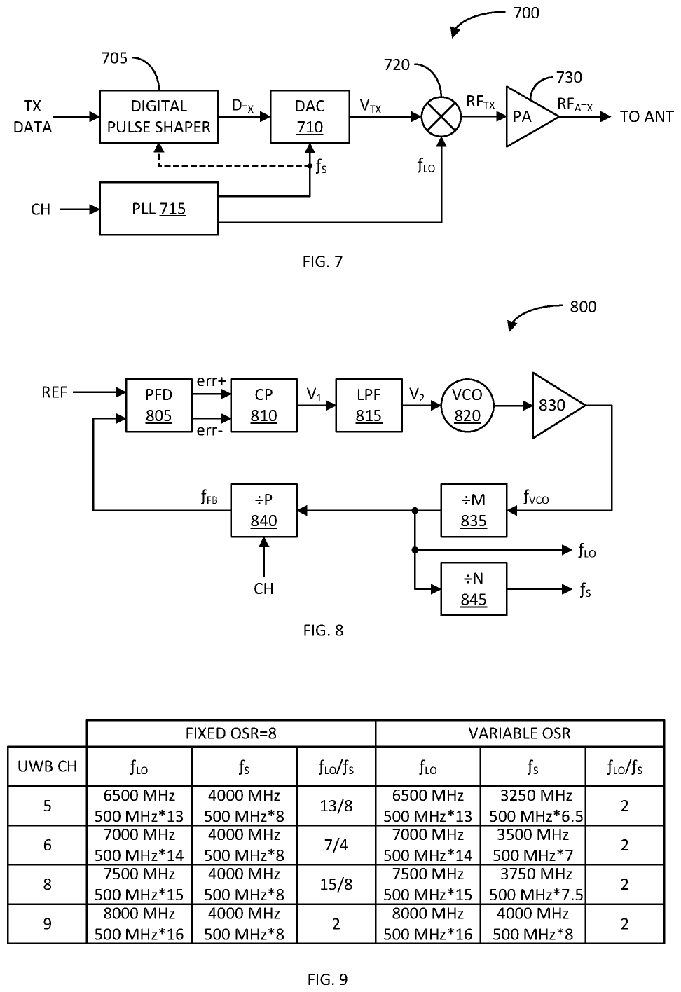

FIG. 7 illustrates a block diagram of another example transmitter 700 in accordance with another aspect of the disclosure. A drawback of the transmitter 100 previously discussed is that it requires two PLLs: the DAC sampling PLL 115 configured to generate the DAC sampling signal f_{S} and the RF LO PLL 125 configured to generate the LO signal f_{LO}. Thus, for transmitter 100, significant circuit area or integrated circuit (IC) area or footprint is needed to accommodate the two PLLs 115 and 125. Further, both PLLs 115 and 125 are consuming power in generating the DAC sampling signal f_{S} and the LO signal f_{LO}, respectively. As discussed further herein, the transmitter 700 includes a single PLL configured to generate both the DAC sampling signal f_{S} and the LO signal f_{LO}.

In particular, the transmitter 700 includes a digital pulse shaper 705, a digital-to-analog converter (DAC) 710, a dual-output phase lock loop (PLL) 715, a frequency-upconverting mixer 720, and a power amplifier (PA) 730. It shall be understood that the transmitter 700 is an example, and the transmitter 700 may be configured differently including more or less components as exemplified in FIG. 7. Further, it shall be understood that the transmitter 700 may be part of a transceiver including an associated receiver.

The digital pulse shaper 705 is configured to receive transmit (Tx) data, and generate a transmit digital signal D_{TX} based on the Tx data. For example, the transmit digital signal D_{TX} may be samples of a pulse, such as an ultra-wideband (UWB) pulse, indicative of logic information of the current Tx data. For instance, if the current Tx data is a logic one (1), the digital pulse shaper 705 may generate the transmit digital signal D_{TX} to include a positive pulse. If the current Tx data is a logic zero (0), the digital pulse shaper 705 may generate the transmit digital signal D_{TX} to include a negative pulse.

Alternatively, the digital pulse shaper 705 may generate the transmit digital signal D_{TX} to represent a ternary logic signal. For example, a previously discussed, the Tx input data could be 2 bits of parallel inputs at 500 mega bits per second (Mbps), with bit<1> as a logic one (1) and bit<0> as another logic one (1), then the digital pulse shaper 105 may generate the transmit digital signal D_{TX} to include a positive pulse. Similarly, if the 2 bits of parallel inputs send a logic one (1) at bit<1> and a logic zero (0) at bit<0>, then the digital pulse shaper 105 may generate the transmit digital signal D_{TX} to include a negative pulse. And if bit<1> of the 2 bits Tx data input is a logic zero (0), regardless of the status of bit<0>, which could be considered as a “don't care”, then the digital pulse shaper 105 may generate the transmit digital signal D_{TX} to include no pulse (or an absence of a pulse).

The digital pulse shaper 705 may generate the transmit digital signal D_{TX} based on a DAC sampling signal f_{S} generated by the dual-output PLL 715. As previously discussed, the DAC sampling signal f_{S} sets the number of samples of the transmit digital signal D_{TX} to generate a UI of a pulse. If the number of samples to generate a UI of a pulse is two (2), it may be said that the DAC sampling signal f_{S} has an OSR of 2×. If the number of samples to generate a UI of a pulse is four (4), the DAC sampling signal f_{S} has an OSR of 4×. And, if the number of samples to generate a UI of a pulse is eight (8), the DAC sampling signal f_{S} has an OSR of 8×.

The pulses (including no pulse intervals) of the transmit digital signal D_{TX} are generated every UI. Considering the ongoing example, a UI may be 2 ns. Accordingly, the pulses (including no pulse intervals) are generated at a rate of 500 MHz (e.g., ½ ns). If the OSR is 2×, then the frequency of the DAC sampling signal f_{S} is 1 GHz (e.g., 2×500 MHz). If the OSR is 4×, then the frequency of the DAC sampling signal f_{S} is 2 GHz (e.g., 4×500 MHz). And, if the OSR is 8×, then the frequency of the DAC sampling signal f_{S} is 4 GHz (e.g., 8×500 MHz).

The transmit digital signal D_{TX} is provided to the DAC 710, which is configured to convert the transmit digital signal D_{TX} into a transmit analog signal V_{TX}. Although the DAC sampling signal f_{S} generated by the dual-output PLL 715 is provided to the digital pulse shaper 705, the DAC sampling signal f_{S} controls the rate at which the DAC 710 converts the transmit digital signal D_{TX} into the transmit analog signal V_{TX}.

The frequency-upconverting mixer 720 is configured to mix the transmit analog signal V_{TX} with an LO signal f_{LO} also generated by the dual-output PLL 715 to generate a transmit RF signal RF_{TX}. As previously discussed, it shall be understood that the transmitter 700 may include more than one frequency-upconverting mixer stage. For example, the transmitter 700 may include a first mixer stage configured to frequency upconvert the transmit analog signal V_{TX} into an intermediate frequency (IF) transmit signal, and then a second mixer stage configured to frequency upconvert the IF transmit signal into the transmit RF signal RF_{TX}. In this example, the LO signal f_{LO} may serve as the carrier component of the transmit RF signal RF_{TX}.

The PA 730 is configured to amplify the transmit RF signal RF_{TX} to a particular power level for transmission to one or more wireless devices (e.g., in the case of communication applications) and/or one or more objects (e.g., in the case of radar applications). The output of the PA 730 may be coupled to an antenna to radiate the amplified transmit RF signal RF_{ATX} to effectuate the remote transmission to the one or more wireless device and/or objects. As alluded to above, the transmitter 700 may include additional components between the PA 730 and the antenna, such as a directional coupler, power detector, diplexer, duplexer, filter, etc.

FIG. 8 illustrates a block diagram of an example dual-output phase lock loop (PLL) 800 in accordance with another aspect of the disclosure. The dual-output PLL 800 may be an example implementation of the dual-output PLL 715 of transmitter 700. Although the PLLs 715 and 800 are described as having dual outputs, it shall be understood that the PLLs 715 and 800 may each have more than two outputs for generating periodic oscillating signals or clocks.

In particular, the PLL 800 includes a phase-frequency detector (PFD) 805, a charge pump (CP) 810, a low pass filter (LPF) 815, a voltage controlled oscillator (VCO) 820, a buffer 830, a divide-by-M frequency divider 835, a divide-by-P frequency divider 840, and a divide-by-N frequency divider 845.

The PFD 805 is configured to compare the phase-frequency of an input reference signal REF (e.g., a clock) to the phase-frequency of a feedback signal f_{FB} to generate a control signal err+/err− for the charge pump 810. The charge pump 810 is configured to charge or discharge an internal capacitor based on the control signal err+/err−, respectively. For example, if the phase-frequency of the feedback signal f_{FB} is lagging the phase-frequency of the REF signal, then the err+ component of the control signal is asserted and the err− component of the control signal is not asserted; thereby, causing the CP 810 to charge the internal capacitor to increase a voltage V₁. If the phase-frequency of the feedback signal f_{FB} is leading the phase-frequency of the REF signal, then the err+ component of the control signal is not asserted and the err− component of the control signal is asserted; thereby, causing the CP 810 to discharge the internal capacitor to decrease the voltage V₁. Thus, the charge pump is configured to generate a first voltage V₁ based on the control signal err_/err−.

The LPF 815 filters the voltage V₁ to substantially eliminate high frequency components therein so as to generate a VCO frequency control voltage V₂. The VCO 820 is configured to generate a VCO signal f_{VCO} whose frequency is controlled by the voltage V₂ to maintain the feedback signal f_{FB} phase-frequency locked with the REF signal. The VCO signal f_{VCO} is provided to the divide-by-M frequency divider 835 via the buffer 830. The frequency divider 835 is configured to frequency divide the VCO signal f_{VCO} by an integer M to generate the LO signal f_{LO}. Similarly, the LO signal f_{LO} is provided to the frequency divider 845, which is configured to frequency divide the LO signal f_{LO} by an integer N to generate the DAC sampling signal f_{S}. In a like manner, the LO signal f_{LO} is also provided to the frequency divider 840, which is configured to frequency divide the LO signal f_{LO} by an integer P to generate the feedback signal f_{FB} (e.g., through frequency dividers 835 and 840, the feedback signal f_{FB} is based on the VCO signal f_{VCO}). The divider ratio P of the frequency divider 840 may be variable, and may depend on a select channel signal CH. It shall be understood that the PLL 800 is an example, and the PLL 800 may be configured differently including more or less components exemplified in FIG. 8.

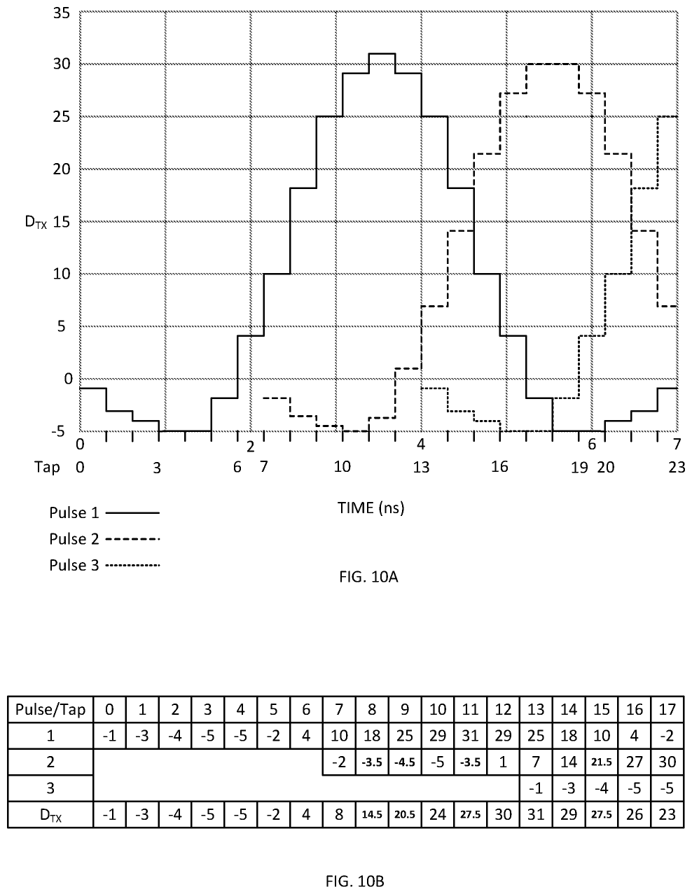

FIG. 9 illustrates a table for comparing a fixed oversampling ratio (OSR) and variable OSR associated with generating transmit digital signal D_{TX} in accordance with another aspect of the disclosure. The left column of the table represents different transmission (e.g., UWB) channels, such as channel 5 in row 1, channel 6 in row 2, channel 8 in row 3, and channel 9 in row 4. The next three (3) columns to the left of the UWB channel column pertain to a fixed OSR of eight (8), and they include the frequency of the LO signal f_{LO}, the frequency of the DAC sampling signal f_{S}, and the ratio of the frequencies f_{LO}/f_{S}. The next three (3) columns, to the left of the three (3) columns pertaining to the fixed OSR of eight (8), pertain to a variable OSR, and they include the frequency of the LO signal f_{LO}, the frequency of the DAC sampling signal f_{S}, and the ratio of the frequencies f_{LO}/f_{S}.

In both the fixed and variable OSR sections, the frequencies of the LO signal f_{LO} for channels CH5, CH6, CH8, and CH9 are 6500 MHz, 7000 MHz, 7500 MHz, and 8000 MHz, respectively. These frequencies may be an integer multiple P of the pulse rate f_{P} or 1/UI (e.g., 1/(2 ns) or 500 MHz). For example, the integer P is 13, 14, 15, and 16 for channels 5, 6, 8, and 9. With regard to the PLL 800, the integer P may correspond to the divider ratio P of frequency divider 840 and the REF signal may have a frequency of 500 MHz. In the case of the fixed OSR=8, the frequency of the DAC sampling f_{S} is fixed at the OSR×1/UI; or in this example, 8×½ ns=8×500 MHz=4000 MHz.

An issue with the fixed OSR is that the frequency divider 845 needs to be implemented as a fractional frequency divider. This is indicated in the table as the column pertaining to the ratio f_{LO}/f_{S}. The ratio f_{LO}/f_{S} is the same as the divider ratio N of frequency divider 845 if the frequency divider 845 were to be configured as a fractional divider. For example, with regard to channel 5, the ratio f_{LO}/f_{S} is 13/8; with regard to channel 6, the ratio f_{LO}/f_{S} is 7/8; with regard to channel 8, the ratio f_{LO}/f_{S} is 15/8; and with regard to channel 9, the ratio f_{LO}/f_{S} is 2. Accordingly for channels 1-3, the frequency divider 845 is configured to produce divider ratios 13/8, 7/4, and 15/8, respectively. Fractional frequency division is very complex (e.g., requiring significant number of components) and typically consumes significant power. It would be more desirable to implement the frequency divider 845 as an integer M divider for design simplicity and reduced power consumption.

With regard to the variable OSR, the frequency divider 845 may be implemented with an integer divider ratio M (e.g., M=2; or more generally, M=2^{T}, where T is a positive integer). Thus, as indicated in the column pertaining to the ratio f_{LO}/f_{S} for the variable OSR, the ratio f_{LO}/f_{S} or the divider ratio M of the frequency divider 845 is set to two (2) for all channels 1-4. However, in doing so, the OSR varies per the current channel. For example, for channel 5, the OSR is 6.5, which corresponds to a DAC sampling frequency f_{S} of 3250 MHz (f_{LO}/2); for channel 6, the OSR=7, which corresponds to a DAC sampling frequency f_{S} of 3500 MHz (f_{LO}/2); for channel 8, the OSR=7.5, which corresponds to a DAC sampling frequency f_{S} of 3750 MHz (f_{LO}/2); and for channel 9, the OSR=8, which corresponds to a DAC sampling frequency f_{S} of 4000 MHz (f_{LO}/2).

With regard to integer OSRs, such as 7 for channel 6, and 8 for channel 9, the digital pulse shaper 105 or 705 may generate the sample coefficients for the transmit digital signal D_{TX} in a similar manner as the digital pulse shaper 105 or 705 generates the sample coefficients for the OSR=8 examples discussed with reference to FIGS. 5A-5B and 6A-6B. That is, sample coefficients are generated at the start and end boundaries of each UI because the OSR is an integer. However, for fractional OSRs, such as 6.5 for channel 5, and 7.5 for channel 8, a sample coefficient may be generated at one boundary (e.g., at the start) of a UI, but a sample coefficients cannot be generated at the other boundary (e.g., at the end) of the UI. The following further elaborates on fractional OSR and solutions as to how to handle the generation of the transmit digital signal D_{TX} based on a fractional OSR.

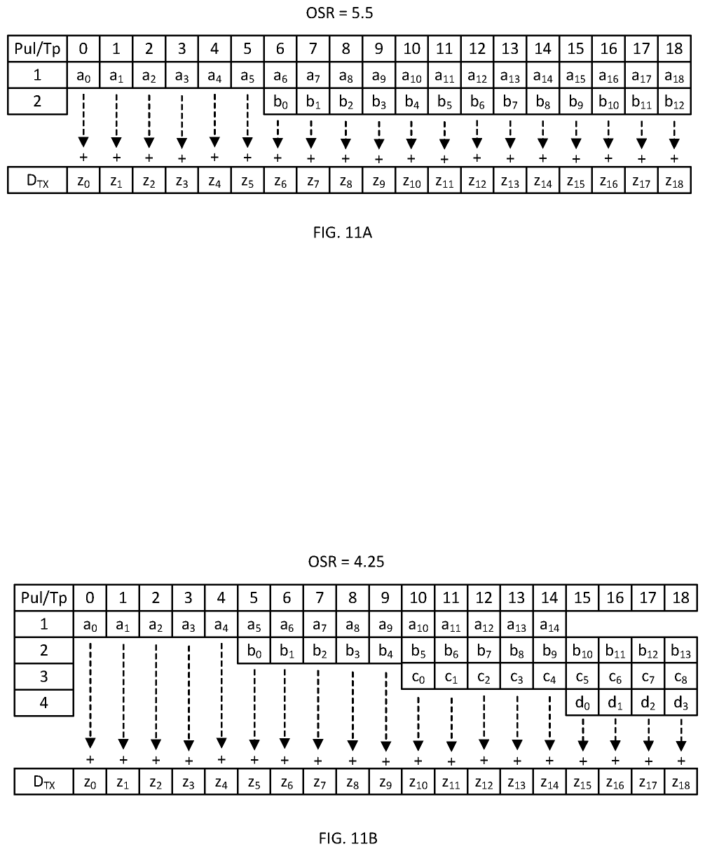

FIG. 10A illustrates a graph of another example set of consecutive transmit digital pulses in accordance with another aspect of the disclosure. The x- or horizontal-axis of the graph represents time in nanoseconds (ns) extending from 0 ns to 7 ns. The y- or vertical-axis of the graph represents amplitude of the transmit digital pulse D_{TX}, extending from −5 to +31. A table, accompanying the graph, is provided as a legend to identify each of the pulses and the bits each of the pulses represents.

In this example, the set of consecutive transmit digital pulses D_{TX} are a set of pulses representing a bit stream of 1/1/1. Further, in accordance with this example, the OSR for the transmit digital signal D_{TX} is 6.5. That is, there are 6.5 samples per UI (e.g., 2 ns). As such, the last sample of every odd UI begins before and terminates after the boundary between the odd and even UIs. Whereas, the last sample of every even UI ends at the boundary between the even and odd UIs.

For example, with regard to the first pulse (“pulse 1”), represented as a solid line, there are 6.5 samples between 0 ns to 2 ns (the first UI), with the seventh sample (with a sample value of 4) beginning before the 2 ns (e.g., at ˜1.846 ns) and ending after the 2 ns (e.g., at ˜2.154 ns). However, the 13^{th} sample (with a sample value of 29) ends at 4 ns (boundary between the first and second UIs). This is because with an OSR of 6.5, there are 13 (integer) samples for every two consecutive UIs. Thus, as discussed further herein, when the fractional part of an OSR is 0.5, there are an integer number of samples per every two consecutive UIs.

With regard to the second pulse (“pulse 2”), represented as a larger dashed line, there are 6 samples between 2 ns to 4 ns (the second UI), with its first sample (with a sample value of −2) not starting at the beginning of the second UI, but at ˜2.154 ns but ending at the end of the second UI at 4 ns. However, the 13^{th} sample (with a sample value of 27) ends at slightly after the third UI at 6.154 ns. Similarly, with a 2UI time interval (6.154 ns-2.154 ns), there are 13 (integer) samples of the second pulse. Again, when the fractional part of an OSR is 0.5, there are an integer number of samples per every two consecutive UIs.

With regard to the third pulse (“pulse 1”), represented as a smaller dashed line, there are 6.5 samples between 4 ns to 6 ns (the third UI), with the seventh sample (with a sample value of 4) beginning before the 6 ns (e.g., at ˜5.846 ns) and ending after the 6 ns (e.g., at ˜6.154 ns). However, the 13^{th} sample of the third pulse (with a sample value of 29) ends at 8 ns (not shown, but the boundary between the third and fourth UIs). Again, this is because with an OSR of 6.5, there are 13 (integer) samples for every two consecutive UIs. And, as mentioned, when the fractional part of an OSR is 0.5, there are an integer number of samples per every two consecutive UIs.

FIG. 10B illustrates a table depicting sets of sample coefficients of the first, second, and third pulses of FIG. 10A and the transmit digital signal D_{TX} at various taps in accordance with another aspect of the disclosure. The left column represents the pulses and the transmit digital signal D_{TX} (e.g., pulse 1 in row 1, pulse 2 in row 2, pulse 3 in row 3, and D_{TX} in row 4). The remaining columns, from left-to-right, represents the different sample coefficients of the pulses and the transmit digital signal D_{TX} corresponding to taps zero (0) to 17, respectively.

For taps 0 to 6, there are no pulses overlapping with the first pulse; and thus, the sample coefficients for the first pulse, as well as the transmit digital signal D_{TX}, for taps 0-6, are −1, −3, −4, −5, −5, −2, and 4, respectively. At tap 7, the first pulse begins to overlap with the second pulse. The sample coefficient of the first pulse at tap 7 is 10, and the sample coefficient of the second pulse at tap 7 is −2. Thus, the transmit digital signal D_{TX} at tap 7 has a sample coefficient of 8 (e.g., 10−2=8). Similarly, for taps 8 to 12, only the first and second pulses overlap; and thus, the sample coefficients for the first and second pulses, and the transmit digital signal D_{TX} for taps 8 to 12 are [18, −3.5, 14.5], [25, −4.5, 20.5], [29, −5, 24], [31, −3.5, 27.5], and [29, 1, 30], respectively. At tap 13, the first and second pulses begin to overlap with the third pulse. Accordingly, the sample coefficients for the first, second, and third pulses, and the transmit digital signal D_{TX} for taps 13 to 17 are [25, 7, −1, 31], [18, 14, −3, 29], [10, 21.5, −4, 27.5], [4, 27, −5, 26], and [−2, 30, −5, 23], respectively.

As explained in more detail further herein, when the OSR is an integer, each positive pulse may have the same set of sample coefficients. For example, with reference to the example OSR=8 depicted in the table of FIG. 5B, the first positive pulse (“pulse 1”) has a set of sample coefficients of [−3, −4, −5, −4, −3, 0, 5, 10, 16, 22, 27, 30, 31, 30, 27, 22, 16, 10, 5, 0, −3, −4, −5, −4, −3]. The second positive pulse (“pulse 2”) has the same set of sample coefficients [−3, −4, −5, −4, −3, 0, 5, 10, 16, 22, 27, 30, 31, 30, 27, 22, 16, 10, 5, 0, −3, −4, −5, −4, −3]. Similarly, with an integer OSR, negative pulses also have the same set of sample coefficients, which is the same as the positive pulse sequence but with the opposite sign, e.g., [3, 4, 5, 4, 3, 0, −5, −10, −16, −22, −27, −30, −31, −30, −27, −22, −16, −10, −5, 0, 3, 4, 5, 4, 3].

However, when the OSR is fractional, the set of sample coefficients of one pulse is based on (e.g., by interpolation) of the set of sample coefficients of an adjacent pulse. For example, with reference again to FIG. 10B, the first sample coefficient (e.g., −2) of the second pulse is a half-weighted interpolation of the first and second sample coefficients (−1 and −3) of the first pulse. Similarly, the second sample value (e.g., −3.5) of the second pulse is a half-weighted interpolation of the second and third sample coefficients (−3 and −4) of the first pulse. Accordingly, it follows that the 3^{rd} to the 11^{th} sample coefficients of the second pulse (−4.5, −5, −3.5, 1, 7, 14, 21.5, 27, and 30) are the half-weighted interpolations of the 2^{nd} and 3^{rd} to the 10^{th} and 11^{th} sample coefficients of the first pulse ([−4, 5], [−5, 5], [−5, 2], [−2, 4], [4, 10], [10, 18], [18, 25], [25, 29], and [29, 31]), respectively. The reason for the interpolation is that the first sample of the second pulse should start at tap 65 because of the fractional OSR=6.5. But because it starts at tap 7, the sample coefficient is corrected to account for the time discrepancy between tap 6.5 and tap 7.

FIG. 11A illustrates a table depicting digital sample coefficients of a pair of consecutive transmit digital pulses associated with a fractional oversampling ratio (OSR) of X.5 (where X is an integer) in accordance with another aspect of the disclosure. Although an OSR of 5.5 is used herein as an example, the algorithm discussed with reference to FIG. 11A is applicable to all 0.5 fractional OSRs.

In a 0.5 OSR, there are two distinct sets of sample coefficients associated with two adjacent or consecutive pulses, respectively. For example, a first positive pulse (“pulse 1”) has a set of sample coefficients of a₀ to a₁₈. Note that the length or the number of sample coefficients of the set for the first pulse may be set to “j” (e.g., j=19). A second positive pulse (“pulse 2”) has a set of sample coefficients of b₀ to bis. Note that the length or the number of sample coefficients of the set for the second pulse may be set to “j” (e.g., j=19). The sequence for the second pulse is skewed by X+1 taps (e.g., it starts at tap 6). Further, the sample coefficients of the set for the second pulse are each a 0.5 weighted interpolation of the sample coefficients of the first pulse (e.g., b₀=1/2*(a₀+a₁), b₁=1/2*(a₁+a₂), b₃=1/2*(a₂+a₃), and so on). Generally, the i^{th} sample coefficient of the second pulse may be given by the following: bᵢ=1/2*(aᵢ+aᵢ₊₁). To assist the interpolation, it is assumed a₁9=0, and b₁₈=1/2*(a₁₈+a₁₉).

As previously discussed, the set of sample coefficients of a negative pulse is the negative sign of the set of sample coefficients of a positive pulse. In other words, the set of sample coefficients of a negative pulse corresponding to the first pulse (“pulse 1”) would be −a₀ to −aⱼ. Similarly, the set of sample coefficients of a negative pulse corresponding to the second pulse (“pulse 2”) would be −b₀ to −bⱼ. If the transmit digital signal D_{TX} is a ternary signal, then a no pulse would have a set of sample coefficients being all zeros. Thus, a no pulse corresponding to the first pulse would have a set of sample coefficients of {a₀ to aⱼ}=0, whereas a no pulse corresponding to the second pulse would have a set of sample coefficients of {b₀ to bⱼ}=0. Further, as previously discussed, the transmit digital signal D_{TX} would include a sum of the sets of sample coefficients Z₀ to Zⱼ of overlapping pulses. Thus, for a 0.5 fractional OSR, the following relationships may be applicable:
a positive first pulse={a₀ to aⱼ} for taps 0 to j, respectively
a positive second pulse={b₀ to bⱼ} for taps X+1 to X+j, respectively, wherein bᵢ=1/2*(aᵢ+aᵢ₊₁), assume aⱼ₊₁=0 for interpolation
a negative first pulse=−{a₀ to a} for taps 0 to j, respectively
a negative second pulse={b₀ to bⱼ} for taps X+1 to X+j, respectively, wherein bᵢ=1/2*(aᵢ+aᵢ₊₁), assume aⱼ₊₁=0 for interpolation
a no first pulse={a₀ to aⱼ}=0 for taps 0 to j, respectively
a no second pulse={b₀ to bⱼ}=0 for taps X+1 to X+j, respectively

FIG. 11B illustrates a table depicting digital sample coefficients of a pair of consecutive transmit digital pulses associated with a fractional oversampling ratio (OSR) of X.25 (where X is an integer) in accordance with another aspect of the disclosure. Although an OSR 4.25 is used herein as an example, the algorithm discussed with reference to FIG. 11B is applicable to all 0.25 fractional OSRs.

In a 0.25 OSR, there are four distinct sets of sample coefficients associated with four adjacent or consecutive pulses, respectively. For example, a first positive pulse (“pulse 1”) has a set of sample coefficients of a₀ to a₁₄. Note that the length or the number of sample values of the sequence for the first pulse may be set to “j” (e.g., j=15).

A second positive pulse (“pulse 2”) has a set of sample coefficients of b₀ to b₁₃. Note that the length or the number of sample coefficients of the set for the second pulse may be “j” (e.g., j=15). The set of sample coefficients for the second pulse is skewed by X+1 taps (e.g., it starts at tap 5). Further, the set of sample coefficients for the second pulse is based on (e.g., by a 0.25/0.75 weighted interpolation of) the sample coefficients of the first pulse (e.g., b₀=1/4*a₀+3/4*a₁, b₁=1/4*a₁+3/4*a₂, b₃=1/4*a₂+3/4*a₃, and so on). Generally, the i^{th} sample value of the sample coefficient of the second pulse may be given by the following: bᵢ=1/4*aᵢ+3/4*aᵢ₊₁. The theory behind this is that the first coefficient b₀ of the second train of pulse should start at 4.25 tap while it actually starts at the 5^{th} tap, where more weighting should be put on a₁ than a₀.

A third positive pulse (“pulse 3”) has a set of sample coefficients of c₀ to c₁₃. Note that the length or the number of sample values of the sequence for the third pulse may be set to “j” (e.g., j=15). The set of sample coefficients of the third pulse is skewed by 2*(X+1) taps with respect to the set of sample coefficients of the first pulse (e.g., it starts at tap 10). Further, the set of sample coefficients of the third pulse is based on (e.g., by a 0.5 weighted interpolation of) the set of sample coefficients of the first pulse (e.g., c₀=1/2*(a₀+a₁), c₁=1/2*(a₁+a₂), c₃=1/2*(a₂+a₃), and so on). Generally, the ih sample value of the sample coefficient of the third pulse may be given by the following: cᵢ=1/2*(aᵢ+aᵢ₊₁).

A fourth positive pulse (“pulse 4”) has a set of sample coefficients of d₀ to d₁₃. Note that the length or the number of sample values of the sequence for the fourth pulse may be set to “j” (e.g., j=15). The set of sample coefficients of the fourth pulse is skewed by 3*(X+1) taps relative to the start of the set of sample coefficients of the first pulse (e.g., it starts at tap 15). Further, the set of sample coefficients of the second pulse is based on (e.g., a 0.75/0.25 weighted interpolation of) the set of sample coefficients of the first pulse (e.g., d₀=3/4*a₀+1/4*a₁, d₁=3/4*a₁+1/4*a₂, d₃=3/4*a₂+1/4*a₃, and so on). Generally, the i^{th} sample coefficient of the fourth pulse may be given by the following: dᵢ=3/4*aᵢ+1/4*aᵢ₊₁.

As previously discussed, the set of sample coefficients of a negative pulse is the negative sign of a positive pulse. In other words, a negative pulse corresponding to the first pulse (“pulse 1”) would be −a₀ to −aⱼ. A negative pulse corresponding to the second pulse (“pulse 2”) would be −b₀ to −bⱼ. A negative pulse corresponding to the third pulse (“pulse 3”) would be −c₀ to −cⱼ. A negative pulse corresponding to the fourth pulse (“pulse 2”) would be −d₀ to −dⱼ.

If the transmit digital signal D_{TX} is a ternary signal, then a no pulse would have a set of sample coefficients being all zeros. Thus, a no pulse corresponding to the first pulse would be [a₀ to aⱼ]=0; a no pulse corresponding to the second pulse would be [b₀ to bⱼ]=0; a no pulse corresponding to the third pulse would be [c₀ to cⱼ]=0; and a no pulse corresponding to the fourth pulse would be [d₀ to dⱼ]=0. Further, as previously discussed, the transmit digital signal D_{TX} would include a sum of the sets of sample coefficients Z₀ to Zⱼ of overlapping pulses. Thus, for a 0.25 fractional OSR, the following relationship may be applicable:
a positive first pulse={a₀ to aⱼ} for taps 0 to j, respectively
a positive second pulse={b₀ to bⱼ} for taps X+1 to tap X+j, respectively, wherein bᵢ=1/4aᵢ+3/4*aᵢ₊₁
a positive third pulse={c₀ to cⱼ} for taps 2*(X+1) to 2*(X+1)+j−1, respectively, wherein cᵢ=1/2*(aᵢ+aᵢ₊₁)
a positive fourth pulse={d₀ to dⱼ} for taps 3*(X+1) to 3*(X+1)+j−1, respectively, wherein dᵢ=3/4aᵢ+1/4*aᵢ₊₁
a negative first pulse=−{a₀ to aⱼ} for taps 0 to j, respectively
a negative second pulse=−{b₀ to bⱼ} for taps X+1 to tap X+j, respectively, wherein bᵢ=1/4aᵢ+3/4*aᵢ₊₁
a negative third pulse=−{c₀ to cⱼ} for taps 2*(X+1) to 2*(X+1)+j−1, respectively, wherein cᵢ=1/2*(aᵢ+aᵢ₊₁)
a negative fourth pulse=−{d₀ to dⱼ₋₁} for taps 3*(X+1) to 3*(X+1)+j−1, respectively, wherein dᵢ=3/4aᵢ+1/4*aᵢ₊₁
a no first pulse={a₀ to aⱼ}=0 for taps 0 to j, respectively
a no second pulse={b₀ to bⱼ}=0 for taps X+1 to X+j−1, respectively
a no third pulse={c₀ to cⱼ}=0 for taps 2*(X+1) to 2*(X+1)+j−1, respectively
a no fourth pulse={d₀ to dⱼ}=0 for taps 3*(X+1) to 3*(X+1)+j−1, respectively

It shall be understood that the OSR may have a higher fractional order, such as 1/8, 1/16, or generally, 1/2^{T}, where T is a positive integer. The number of distinct sets of sample coefficients for adjacent pulses would be 2^{T}. The set of sample coefficients for the k^{th} positive pulse following the first pulse may be given by the following: kᵢ=(2^{T}−k)/2^{T}*aᵢ+k/2^{T}*aᵢ₊₁. The set of sample coefficients for the k^{th} negative pulse following the first pulse may be given by the following: kᵢ=−[k/2^{T}*aᵢ+(2^{T}×k)/2^{T}*aᵢ₊₁]. The set of sample coefficients for the k^{th} no pulse following the first pulse may be given by the following: kᵢ=0. The k^{th} pulse following the first pulse may be skewed with respect to the first pulse by k*(X+1) taps. And the k^{th} pulse following the first pulse may have a length of j.

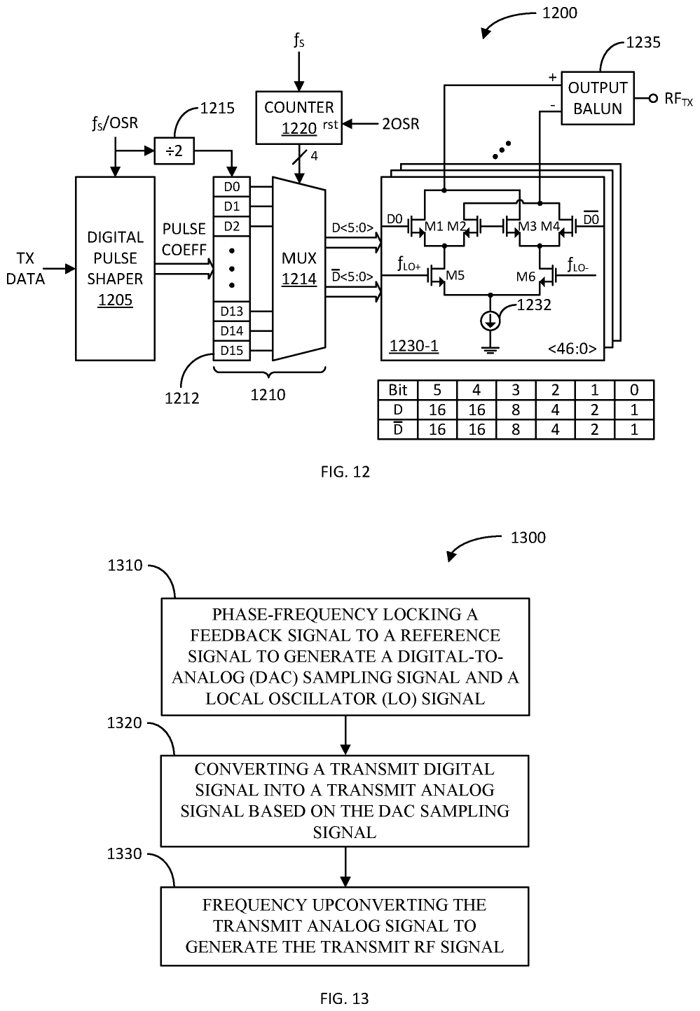

FIG. 12 illustrates a block diagram of at least a portion of an example transmitter 1200 in accordance with another aspect of the disclosure. The transmitter 1200 includes a digital pulse shaper 1205, a data serializer (e.g., 16-to-1 or 16-1) 1210 including an input register 1212 and a multiplexer 1214, a frequency divider 1215, a counter 1220, a set of integrated DAC-mixer slices 1230-1 to 1230-46, and an output balun 1235. Each of the set of integrated DAC-mixer slices 1230-1 to 1230-46 includes a set of n-channel metal oxide semiconductor field effect transistors (NMOS FETs) M1-M6 and a current source 1232.

The digital pulse shaper 1205 is configured to receive the transmit data (Tx Data) (e.g., a bit stream). The digital pulse shaper 1205 is configured to output in parallel pulse sample coefficients for two consecutive UIs at half the pulse or bit rate 1/(2*UI) (e.g., 1/(2*2 ns)=¼ ns=250 MHz). The digital pulse shaper 1205 may be driven by a clock with frequency at the pulse rate, which is also equal to the DAC sampling frequency f_{S} divided by the current OSR (f_{S}/OSR); which in this example, the current OSR may be one of 6.5, 7, 7.5 or 8. The DAC sampling signal f_{S} may have been generated by the dual-output PLL 715 or 800 previously discussed.

Accordingly, the input register 1212 of the 16-1 serializer 1210 is configured to receive the pulse sample coefficients D0 to D12, or D0 to D13, or D0 to D14, or D0 to D15 in parallel from the digital pulse shaper 1205. For example, if the current OSR=6.5, the input register 1212 receives pulse sample coefficients D0 to D12, as there are 13 pulse sample coefficients for two consecutive UIs. If the current OSR=7, the input register 1212 receives pulse sample coefficients D0 to D13, as there are 14 pulse sample coefficients for two consecutive UIs. If the current OSR=7.5, the input register 1212 receives pulse sample coefficients D0 to D14, as there are 15 pulse sample coefficients for two consecutive UIs. If the current OSR=8, the input register 1212 receives pulse sample coefficients D0 to D15, as there are 16 pulse sample coefficients for two consecutive UIs. Accordingly, the input register 1212 receives the pulse sample coefficients at a rate of 1/(2*UI), which is controlled by a clock generated by the frequency divider 1215 dividing by two (2) the pulse rate frequency f_{S}/OSR.

The counter 1220 is driven by the DAC sampling signal f_{S} generated by the dual-output PLL 715 or 800. The counter 1220 is further configured to receive the reset signal for the count limit, which is 2*OSR. As previously discussed, if the current OSR is 6.5, then there are 13 pulse sample coefficients to be outputted by the multiplexer 1214 for each cycle of the counter 1220. If the current OSR is 7, then there are 14 pulse sample coefficients to be outputted by the multiplexer 1214 for each cycle of the counter 1220. If the current OSR is 7.5, then there are 15 pulse sample coefficients to be outputted by the multiplexer 1214 for each cycle of the counter 1220. And, if the current OSR is 8, then there are 16 pulse sample coefficients to be outputted by the multiplexer 1214 for each cycle of the counter 1220. The counter 1220 outputs the index (e.g., 4 bits) of the current pulse sample coefficient to be outputted by the multiplexer 1214.

As mentioned, the multiplexer 1214 is configured to output the current pulse sample coefficient as indicated by the pulse sample index generated by the counter 1220 from the set of pulse sample coefficients stored in the input register 1212. The multiplexer 1214 includes differential outputs D<5:0> and D̅<5:0> for generating a differential binary code based on the current pulse sample coefficient received from the input register 1212. The differential outputs D<5:0> and D̅<5:0> control set of integrated DAC-mixer slices 1230-1 to 1230-46, respectively.

With reference to the table provided in FIG. 12, D/D̅, in this example, are six (6) bits. Bit <5> controls 16 integrated DAC-mixer slices; bit<4> controls 16 integrated DAC-mixer slices; bit<3> controls eight (8) integrated DAC-mixer slices; bit<2> controls four (4) integrated DAC-mixer slices; bit<1> controls two (2) integrated DAC-mixer slices; and bit<0> controls one (1) integrated DAC-mixer slices. When the pulse coefficient is positive, weight data is sent on D (e.g., gates of FET M1) and zero (0) on D̅ (e.g., gates of FET M4). When the pulse coefficient is negative, weight data is sent on D̅ (e.g., gates of FET M4) and zero (0) on D (e.g., gates of FET M1).

The LO signal f_{LO} generated by the dual-output PLL 715 or 800 may be a differential signal f_{LO+}/f_{LO-}, wherein the positive LO signal f_{LO+} is provided to the corresponding gates of the NMOS FETs M5 of the integrated DAC-mixer slices 1230-1 to 1230-46, respectively; and the negative LO signal f_{LO-} is provided to the corresponding gates of the NMOS FETs M6 of the integrated DAC-mixer slices 1230-1 to 1230-46, respectively.

For each of the integrated DAC-mixer slices 1230-1 to 1230-46: the NMOS FETs M1 and M5, and the current source 1232 are coupled in series between a positive input (+) of the output balun 1235 and a lower voltage rail (e.g., ground); the NMOS FETs M4 and M6, and the current source 1232 are coupled in series between a negative input (−) of the output balun 1235 and the lower voltage rail; the NMOS FET M2 includes a drain coupled to the drain of NMOS FET M4, and a source coupled to a source of NMOS FET; the NMOS FET M3 includes a drain coupled to a drain of NMOS FET M1, and a source coupled to a source of NMOS FET M4; and the gates of NMOS FETs M2 and M3 are coupled together. The set of integrated DAC-mixer slices 1230-1 to 1230-46 are configured to generate a differential transmit RF signal at the differential inputs of the output balun 1235. Accordingly, the output balun 1235 is configured to generate a single-ended transmit RF signal RF_{TX}, which may be provided to the PA 730 for amplification and subsequent transmission into free space by a corresponding antenna.

As mentioned above, the transmitter 1200 may be an example implementation to effectuate a 0.5 fractional OSRs. If, for example, 0.25 fractional OSR is required: the digital pulse shaper 1205 may be configured to output in parallel pulse sample coefficients for four (4) UIs; the frequency divider 1215 may have a divider ratio of four (4); the size of the input register 1212 of the serializer 1210 may be set to accommodate pulse sample coefficients of length 4UIs; and the reset input of the counter 1220 may be configured to receive a count limit of 4 times the current OSR.

In general, the transmitter 1200 may be implemented to effectuate a 1/2^{T} fractional OSR. In such case: the digital pulse shaper 1205 may be configured to output in parallel pulse sample coefficients for 2^{T} UIs; the frequency divider 1215 may have a divider ratio of 2^{T}; the size of the input register 1212 of the serializer 1210 may be set to accommodate pulse sample coefficients of length 2^{T} UIs; and the reset input of the counter 1220 may be configured to receive a count limit of 2^{T} times the current OSR.

FIG. 13 illustrates a flow diagram of an example method 1300 of generating a transmit radio frequency (RF) signal in accordance with another aspect of the disclosure. The method 1300 includes phase-frequency locking a feedback signal to a reference signal to generate a digital-to-analog (DAC) sampling signal and a local oscillator (LO) signal (block 1310). Examples of means for phase-frequency locking a feedback signal to a reference signal to generate a digital-to-analog (DAC) sampling signal and a local oscillator (LO) signal include PLL 715 and 800.

The method 1300 further includes converting a transmit digital signal into a transmit analog signal based on the DAC sampling signal (block 1320). Examples of means for converting a transmit digital signal into a transmit analog signal based on the DAC sampling signal the digital pulse shaper 705 and the DAC 710, and the digital pulse shaper 1205, frequency divider 1215, serializer 1210 including input register 1212 and multiplexer 1214, counter 1220, the set of DAC-mixer slices 1230-1 to 1230-46, and the output balun 1235.

Additionally, the method 1300 includes frequency upconverting the transmit analog signal to generate the transmit RF signal (block 1330). Examples of means for frequency upconverting the transmit analog signal to generate the transmit RF signal include the mixer 720, and the set of DAC-mixer slices 1230-1 to 1230-46 including the output balun 1235.

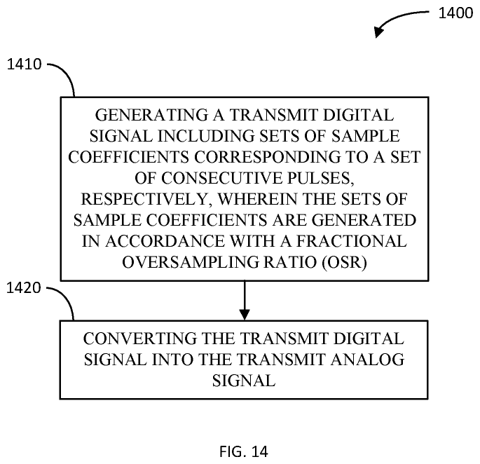

FIG. 14 illustrates a flow diagram of an example method 1400 of generating a transmit analog signal in accordance with another aspect of the disclosure. The method 1400 includes generating a transmit digital signal including sets of sample coefficients corresponding to a set of consecutive pulses, respectively, wherein the sets of sample coefficients are generated in accordance with a fractional oversampling ratio (OSR) (block 1410). Examples of means for generating a transmit digital signal including sets of sample coefficients corresponding to a set of consecutive pulses, respectively, wherein the sets of sample coefficients are generated in accordance with a fractional oversampling ratio (OSR) include the digital pulse shapers 705 and 1205.

The method 1400 further includes converting the transmit digital signal into the transmit analog signal (block 1420). Examples of means for converting the transmit digital signal into the transmit analog signal include the DAC 710 and the set of DAC-mixer slices 1230-1 to 1230-46 including the output balun 1235.

The following provides an overview of aspects of the present disclosure:

Aspect 1: A transmitter, comprising a phase lock loop (PLL) configured to generate a digital-to-analog (DAC) sampling signal and a local oscillator (LO) signal; a digital-to-analog (DAC) converter configured to convert a transmit digital signal into a transmit analog signal based on the DAC sampling signal; and a mixer configured to frequency upconvert the transmit analog signal based on the LO signal.

Aspect 2: The transmitter of aspect 1, wherein the PLL is configured to maintain a ratio of a first frequency of the LO signal to a second frequency of the DAC sampling signal substantially constant for a set of different channels.

Aspect 3: The transmitter of aspect 2, wherein the ratio of the first frequency to the second frequency is substantially two (2).

Aspect 4: The transmitter of aspect 3, wherein the first frequency of the LO signal is substantially 6500 mega Hertz (MHz) and the second frequency of the DAC sampling signal is 3250 MHz for one of the set of different transmit channels.

Aspect 5: The transmitter of aspect 3 or 4, wherein the first frequency of the LO signal is substantially 7000 mega Hertz (MHz) and the second frequency of the DAC sampling signal is substantially 3500 MHz for one of the set of different transmit channels.

Aspect 6: The transmitter of any one of aspects 3-5, wherein the first frequency of the LO signal is substantially 7500 mega Hertz (MHz) and the second frequency of the DAC sampling signal is 3750 MHz for one of the set of different transmit channels.

Aspect 7: The transmitter of any one of aspects 3-6, wherein the first frequency of the LO signal is substantially 8000 mega Hertz (MHz) and the second frequency of the DAC sampling signal is substantially 4000 MHz for one of the set of different transmit channels.

Aspect 8: The transmitter of any one of aspects 1-7, wherein the PLL comprises a first frequency divider configured to frequency divide the LO signal by an integer to generate the DAC sampling signal.

Aspect 9: The transmitter of aspect 8, wherein the PLL further comprises: a phase-frequency detector (PFD) configured to: receive a reference signal and a feedback signal, and generate a control signal based on a phase-frequency difference between the reference signal and the feedback signal; a charge pump configured to generate a first voltage based on the control signal; a low pass filter (LPF) configured to generate a second voltage based on the first voltage; and a voltage controlled oscillator (VCO) configured to generate a VCO signal based on the second voltage, wherein the LO signal is based on the VCO signal.

Aspect 10: The transmitter of aspect 9, wherein the PLL further comprises a second frequency divider configured to generate the feedback signal based on the VCO signal.

Aspect 11: The transmitter of aspect 10, wherein the second frequency divider is configured to frequency divide based on a channel signal.

Aspect 12: The transmitter of aspect 10 or 11, wherein the PLL further comprises a second divider configured to frequency divide the VCO signal to generate the LO signal.

Aspect 13: The transmitter of any one of aspects 1-12, further comprising a digital pulse shaper configured to generate the transmit digital signal as a set of consecutive pulses, wherein adjacent pulses are spaced apart by a unit interval (UI).

Aspect 14: The transmitter of aspect 13, wherein the digital pulse shaper is configured to generate the set of consecutive pulses based on an oversampling ratio (OSR) indicating a number of samples per UI.

Aspect 15: The transmitter of aspect 14, wherein the OSR is a fractional OSR.

Aspect 16: The transmitter of aspect 15, wherein the fractional OSR has a fraction of 0.5.

Aspect 17: The transmitter of aspect 16, wherein the digital pulse shaper is configured to: generate a first set of sample coefficients for a first pulse of the set of consecutive pulses; and generate a second set of sample coefficients for a second pulse of the set of consecutive pulses, wherein the first pulse is adjacent to the second pulse, and wherein the second set of sample coefficients is based on the first set of sample coefficients.

Aspect 18: The transmitter of aspect 17, wherein each sample coefficient of the second set is an interpolation of two sample coefficients of the first set.

Aspect 19: The transmitter of any one of aspects 15-18, wherein the fractional OSR has a fraction of 0.25.

Aspect 20: The transmitter of aspect 19, wherein the digital pulse shaper is configured to: generate a first set of sample coefficients for a first pulse of the set of consecutive pulses; generate a second set of sample coefficients for a second pulse of the set of consecutive pulses, wherein the first pulse is adjacent to the second pulse, and wherein the second set of sample coefficients is based on the first set of sample coefficients; generate a third set of sample coefficients for a third pulse of the set of consecutive pulses, wherein the second pulse is adjacent to the third pulse, and wherein the third set of sample coefficients is based on the first set of sample coefficients; and generate a fourth set of sample coefficients for a fourth pulse of the set of consecutive pulses, wherein the third pulse is adjacent to the fourth pulse, and wherein the fourth set of sample coefficients is based on the first set of sample coefficients.

Aspect 21: The transmitter of aspect 20, wherein: each sample coefficient of the second set is a first weighted interpolation of two sample coefficients of the first set; each sample coefficient of the third set is a second weighted interpolation of two sample coefficients of the first set, wherein the second weighted interpolation is different than the first weighted interpolation; and each sample coefficient of the fourth set is a third weighted interpolation of two sample coefficients of the first set, wherein the third weighted interpolation is different than the first weighted interpolation.

Aspect 22: The transmitter of any one of aspects 1-21, wherein the DAC and mixer are integrated.

Aspect 23: The transmitter of aspect 22, wherein the integrated DAC-mixer comprises a set of parallel DAC-mixer slices configured to generate a transmit radio frequency (RF) signal based on digital information received from a digital pulse shaper and the LO signal.

Aspect 24: A method of generating a transmit radio frequency (RF) signal, comprising: phase-frequency locking a feedback signal to a reference signal to generate a digital-to-analog (DAC) sampling signal and a local oscillator (LO) signal; converting a transmit digital signal into a transmit analog signal based on the DAC sampling signal; and frequency upconverting the transmit analog signal to generate the transmit RF signal.

Aspect 25: The method of aspect 24, wherein the transmit digital signal comprises a set of consecutive pulses including samples generated in accordance with a fractional oversampling ratio (OSR).

Aspect 26: An apparatus for generating a transmit analog signal, comprising: a digital pulse shaper configured to generate a transmit digital signal including sets of sample coefficients corresponding to a set of consecutive pulses, respectively, wherein the sets of sample coefficients are generated in accordance with a fractional oversampling ratio (OSR); and a digital-to-analog converter (DAC) configured to generate the transmit analog signal based on the transmit digital signal.

Aspect 27: The apparatus of aspect 26, wherein the fractional OSR includes a fraction of 1/2^{T}, wherein T is a positive integer, and wherein the sample coefficients of one or more of the sets of sample coefficients are based on another one of the sets of sample coefficients.

Aspect 28: The apparatus of aspect 27, wherein the sample coefficients of the one or more of the sets of sample coefficients are based on different interpolations of adjacent pairs of sample coefficients of the another one of the sets of sample coefficients, respectively.

Aspect 29: A method of generating a transmit analog signal, comprising: generating a transmit digital signal including sets of sample coefficients corresponding to a set of consecutive pulses, respectively, wherein the sets of sample coefficients are generated in accordance with a fractional oversampling ratio (OSR); and converting the transmit digital signal into the transmit analog signal.

Aspect 30: The method of aspect 29, wherein the fractional OSR includes a fraction of 1/2^{T}, wherein T is a positive integer, and wherein the sample coefficients of one or more of the sets of sample coefficients are based on another one of the sets of sample coefficients.

Aspect 31: An apparatus for generating a transmit radio frequency (RF) signal, comprising: means for phase-frequency locking a feedback signal to a reference signal to generate a digital-to-analog (DAC) sampling signal and a local oscillator (LO) signal; means for converting a transmit digital signal into a transmit analog signal based on the DAC sampling signal; and means for frequency upconverting the transmit analog signal to generate the transmit RF signal.

Aspect 32: An apparatus for generating a transmit analog signal, comprising: means for generating a transmit digital signal including sets of sample coefficients corresponding to a set of consecutive pulses, respectively, wherein the sets of sample coefficients are generated in accordance with a fractional oversampling ratio (OSR); and means for converting the transmit digital signal into the transmit analog signal.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed:

1. A transmitter, comprising:
a phase lock loop (PLL) configured to generate a digital-to-analog (DAC) sampling signal and a local oscillator (LO) signal;
a digital-to-analog (DAC) converter configured to convert a transmit digital signal into a transmit analog signal based on the DAC sampling signal; and
a mixer configured to frequency upconvert the transmit analog signal based on the LO signal.

2. The transmitter of claim 1, wherein the PLL is configured to maintain a ratio of a first frequency of the LO signal to a second frequency of the DAC sampling signal substantially constant for a set of different transmit channels.

3. The transmitter of claim 2, wherein the ratio of the first frequency to the second frequency is substantially two (2).

4. The transmitter of claim 3, wherein the first frequency of the LO signal is substantially 6500 mega Hertz (MHz) and the second frequency of the DAC sampling signal is 3250 MHz for one of the set of different transmit channels.

5. The transmitter of claim 3, wherein the first frequency of the LO signal is substantially 7000 mega Hertz (MHz) and the second frequency of the DAC sampling signal is substantially 3500 MHz for one of the set of different transmit channels.

6. The transmitter of claim 3, wherein the first frequency of the LO signal is substantially 7500 mega Hertz (MHz) and the second frequency of the DAC sampling signal is 3750 MHz for one of the set of different transmit channels.

7. The transmitter of claim 3, wherein the first frequency of the LO signal is substantially 8000 mega Hertz (MHz) and the second frequency of the DAC sampling signal is substantially 4000 MHz for one of the set of different transmit channels.

8. The transmitter of claim 1, wherein the PLL comprises a first frequency divider configured to frequency divide the LO signal by an integer to generate the DAC sampling signal.

9. The transmitter of claim 8, wherein the PLL further comprises:
a phase-frequency detector (PFD) configured to:
receive a reference signal and a feedback signal; and
generate a control signal based on a phase-frequency difference between the reference signal and the feedback signal;
a charge pump configured to generate a first voltage based on the control signal;
a low pass filter (LPF) configured to generate a second voltage based on the first voltage; and
a voltage controlled oscillator (VCO) configured to generate a VCO signal based on the second voltage, wherein the LO signal is based on the VCO signal.

10. The transmitter of claim 9, wherein the PLL further comprises a second frequency divider configured to generate the feedback signal based on the VCO signal.

11. The transmitter of claim 10, wherein the second frequency divider is configured to frequency divide based on a channel signal.

12. The transmitter of claim 10, wherein the PLL further comprises a second divider configured to frequency divide the VCO signal to generate the LO signal.

13. The transmitter of claim 1, further comprising a digital pulse shaper configured to generate the transmit digital signal as a set of consecutive pulses, wherein adjacent pulses are spaced apart by a unit interval (UI).

14. The transmitter of claim 13, wherein the digital pulse shaper is configured to generate the set of consecutive pulses based on an oversampling ratio (OSR) indicating a number of samples per UI.

15. The transmitter of claim 14, wherein the OSR is a fractional OSR.

16. The transmitter of claim 15, wherein the fractional OSR has a fraction of 0.5.

17. The transmitter of claim 16, wherein the digital pulse shaper is configured to:
generate a first set of sample coefficients for a first pulse of the set of consecutive pulses; and
generate a second set of sample coefficients for a second pulse of the set of consecutive pulses, wherein the first pulse is adjacent to the second pulse, and wherein the second set of sample coefficients is based on the first set of sample coefficients.

18. The transmitter of claim 17, wherein each sample coefficient of the second set is an interpolation of two sample coefficients of the first set.

19. The transmitter of claim 15, wherein the fractional OSR has a fraction of 0.25.

20. The transmitter of claim 19, wherein the digital pulse shaper is configured to:
generate a first set of sample coefficients for a first pulse of the set of consecutive pulses;
generate a second set of sample coefficients for a second pulse of the set of consecutive pulses, wherein the first pulse is adjacent to the second pulse, and wherein the second set of sample coefficients is based on the first set of sample coefficients;
generate a third set of sample coefficients for a third pulse of the set of consecutive pulses, wherein the second pulse is adjacent to the third pulse, and wherein the third set of sample coefficients is based on the first set of sample coefficients; and
generate a fourth set of sample coefficients for a fourth pulse of the set of consecutive pulses, wherein the third pulse is adjacent to the fourth pulse, and wherein the fourth set of sample coefficients is based on the first set of sample coefficients.

21. The transmitter of claim 20, wherein:
each sample coefficient of the second set is a first weighted interpolation of two sample coefficients of the first set;
each sample coefficient of the third set is a second weighted interpolation of two sample coefficients of the first set, wherein the second weighted interpolation is different than the first weighted interpolation; and
each sample coefficient of the fourth set is a third weighted interpolation of two sample coefficients of the first set, wherein the third weighted interpolation is different than the first weighted interpolation.

22. The transmitter of claim 1, wherein the DAC and mixer are integrated.

23. The transmitter of claim 22, wherein the integrated DAC-mixer comprises a set of parallel DAC-mixer slices configured to generate a transmit radio frequency (RF) signal based on digital information received from a digital pulse shaper and the LO signal.

24. A method of generating a transmit radio frequency (RF) signal, comprising:
phase-frequency locking a feedback signal to a reference signal to generate a digital-to-analog (DAC) sampling signal and a local oscillator (LO) signal;
converting a transmit digital signal into a transmit analog signal based on the DAC sampling signal; and
frequency upconverting the transmit analog signal to generate the transmit RF signal.

25. The method of claim 24, wherein the transmit digital signal comprises a set of consecutive pulses including samples generated in accordance with a fractional oversampling ratio (OSR).

26. An apparatus for generating a transmit analog signal, comprising:
a digital pulse shaper configured to generate a transmit digital signal including sets of sample coefficients corresponding to a set of consecutive pulses, respectively, wherein the sets of sample coefficients are generated in accordance with a fractional oversampling ratio (OSR); and
a digital-to-analog converter (DAC) configured to generate the transmit analog signal based on the transmit digital signal.

27. The apparatus of claim 26, wherein the fractional OSR includes a fraction of 1/2^{T}, wherein T is a positive integer, and wherein the sample coefficients of one or more of the sets of sample coefficients are based on another one of the sets of sample coefficients.

28. The apparatus of claim 27, wherein the sample coefficients of the one or more of the sets of sample coefficients are based on different interpolations of adjacent pairs of sample coefficients of the another one of the sets of sample coefficients, respectively.

29. A method of generating a transmit analog signal, comprising:
generating a transmit digital signal including sets of sample coefficients corresponding to a set of consecutive pulses, respectively, wherein the sets of sample coefficients are generated in accordance with a fractional oversampling ratio (OSR); and
converting the transmit digital signal into the transmit analog signal.

30. The method of claim 29, wherein the fractional OSR includes a fraction of 1/2^{T}, wherein T is a positive integer, and wherein the sample coefficients of one or more of the sets of sample coefficients are based on another one of the sets of sample coefficients.
